(19) United States
(12) Patent Application Publication
(10) Pub. No.: US 2025/0176111 A1
(43) Pub. Date: May 29, 2025

(54) SEMICONDUCTOR PACKAGE AND METHOD OF MANUFACTURING THE SAME

(71) Applicant: Samsung Electronics Co., Ltd., Suwon-si, Gyeonggi-do (KR)

(72) Inventors: Kyoungok JUNG, Suwon-si (KR); Jakyoung GU, Suwon-si (KR); Kyungtae KIM, Suwon-si (KR); Minsoo KIM, Suwon-si (KR); Hyunwoong HAN, Suwon-si (KR)

(73) Assignee: Samsung Electronics Co., Ltd., Suwon-si, Gyeonggi-do (KR)

(21) Appl. No.: 18/939,964

(22) Filed: Nov. 7, 2024

(30) Foreign Application Priority Data
Nov. 23, 2023 (KR) 10-2023-0164515

(51) Int. Cl. H05K 3/24; H01L 21/48; H01L 23/00; H01L 23/498; H01L 25/03; H05K 1/11; H05K 1/18

(52) U.S. Cl. CPC H05K 3/243; H01L 21/4853; H01L 21/4857; H01L 21/486; H01L 23/49811; H01L 23/49822; H01L 23/49833; H01L 23/49838; H05K 1/113; H05K 1/181; H01L 24/16; H01L 24/32; H01L 24/73; H01L 25/03; H01L 2224/16227; H01L 2224/16238; H01L 2224/32225; H01L 2224/73204; H01L 2924/15174; H05K 2201/09472; H05K 2203/092

(57) ABSTRACT

A method of manufacturing a semiconductor package includes forming a metal seed layer on a metal pad, coating a photoresist on the metal seed layer and exposing and developing the photoresist to form an opening, performing ion implantation into a surface of the photoresist and a surface of the metal seed layer exposed by the opening, filling the opening with a metal material to form a metal post electrically connected to the metal pad, and removing the photoresist.

### CROSS-REFERENCE TO RELATED APPLICATION

This application is based on and claims priority under 35 U.S.C. § 119 to Korean Patent Application No. 10-2023-0164515, filed on Nov. 23, 2023, in the Korean Intellectual Property Office, the disclosure of which is incorporated by reference herein in its entirety.

### BACKGROUND

The inventive concepts relate to semiconductor packages and methods of manufacturing the same, and more particularly, to fan-out semiconductor packages and methods of manufacturing the same.

As the electronics industry advances rapidly and the demands of users increase, electronic devices are being more miniaturized, becoming more multifunctional, and have a larger capacity, and thus, highly-integrated semiconductor chips are needed. Therefore, semiconductor packages, which secure connection reliability and include highly-integrated semiconductor chips where the number of connection terminals for input/output (I/O) has increased, have been proposed. For example, fan-out semiconductor packages where an interval between connection terminals increases for preventing interference between the connection terminals are being developed.

### SUMMARY

The inventive concepts provide methods of manufacturing a semiconductor package, which may increase the degree of curing of a surface of a photoresist through ion implantation, reduce a phenomenon where compositions of a photoresist are dissolved by a plating solution in a plating process, and easily remove a residual material of a cured photoresist, thereby securing stability in a post plating process.

The inventive concepts are not limited to the aforesaid, and some aspects of the inventive concepts that are not described herein will be clearly understood by those of ordinary skill in the art from descriptions below.

A method of manufacturing a semiconductor package according to an example embodiment includes forming a first wiring structure including a plurality of first wiring patterns and a first insulation layer surrounding the plurality of first wiring patterns, the first wiring structure including a chip mount region and an outer region surrounding the chip mount region, the plurality of first wiring patterns including a plurality of first connection pads, coating a photoresist on the first wiring structure and exposing and developing the photoresist to form a plurality of openings on the outer region of the first wiring structure, performing ion implantation on a surface of the photoresist and surfaces of the plurality of first connection pads exposed by the plurality of openings, filling the plurality of openings with a conductive material to form a plurality of conductive posts connected to the plurality of first connection pads, removing the photoresist, placing a semiconductor chip on the chip mount region of the first wiring structure, forming an encapsulant surrounding the semiconductor chip and the plurality of conductive posts, and forming a second wiring structure on the encapsulant, the second wiring structure including a plurality of second wiring patterns, a plurality of second connection pads electrically connected to the plurality of conductive posts, and a second insulation layer surrounding the plurality of second wiring patterns.

A method of manufacturing a semiconductor package according to an example embodiment includes forming a metal seed layer on a metal pad, coating a photoresist on the metal seed layer and exposing and developing the photoresist to form an opening, performing ion implantation on a surface of the photoresist and a surface of the metal seed layer exposed by the opening, filling the opening with a metal material to form a metal post electrically connected to the metal pad, and removing the photoresist.

A method of manufacturing a semiconductor package according to an example embodiment includes preparing a supporting substrate, forming a first wiring structure on the supporting substrate, the first wiring structure including a first chip mount region and a first outer region surrounding the first chip mount region, coating a photoresist on the first wiring structure and exposing and developing the photoresist to form a plurality of openings on the first outer region of the first wiring structure, performing ion implantation on an upper surface and a sidewall of the photoresist and an upper surface of the first wiring structure exposed by the plurality of openings, performing rinsing treatment and acid treatment on the supporting substrate, filling the plurality of openings with a conductive material to form a plurality of conductive posts, removing the photoresist, placing a first semiconductor chip on the first chip mount region of the first wiring structure, forming an encapsulant surrounding the first semiconductor chip and the plurality of conductive posts, forming a second wiring structure on the encapsulant, the second wiring structure including a second chip mount region and a second outer region surrounding the second chip mount region, and placing a second semiconductor chip on the second chip mount region of the second wiring structure.

### BRIEF DESCRIPTION OF THE DRAWINGS

Example embodiments will be more clearly understood from the following detailed description taken in conjunction with the accompanying drawings in which:

FIG. 1 is a cross-sectional view illustrating main elements of a semiconductor package according to an example embodiment;

FIG. 2 is an enlarged cross-sectional view of a region CX1 of FIG. 1;

FIG. 3 is a cross-sectional view illustrating main elements of a semiconductor package according to an example embodiment;

FIG. 4 is an enlarged cross-sectional view of a region CX2 of FIG. 3;

FIG. 5 is a flowchart illustrating a method of manufacturing a semiconductor package, according to an example embodiment;

FIGS. 6 to 17 are diagrams illustrating in process sequence a method of manufacturing a semiconductor package, according to an example embodiment;

FIG. 18 is a flowchart illustrating a method of manufacturing a semiconductor package, according to an example embodiment;

FIGS. 19 to 22 are diagrams illustrating, according to process sequence, a method of manufacturing a semiconductor package, according to an example embodiment; and

FIG. 23 is a configuration diagram schematically illustrating a configuration of a semiconductor package according to an example embodiment.

### DETAILED DESCRIPTION

Hereinafter, some example embodiments will be described in detail with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

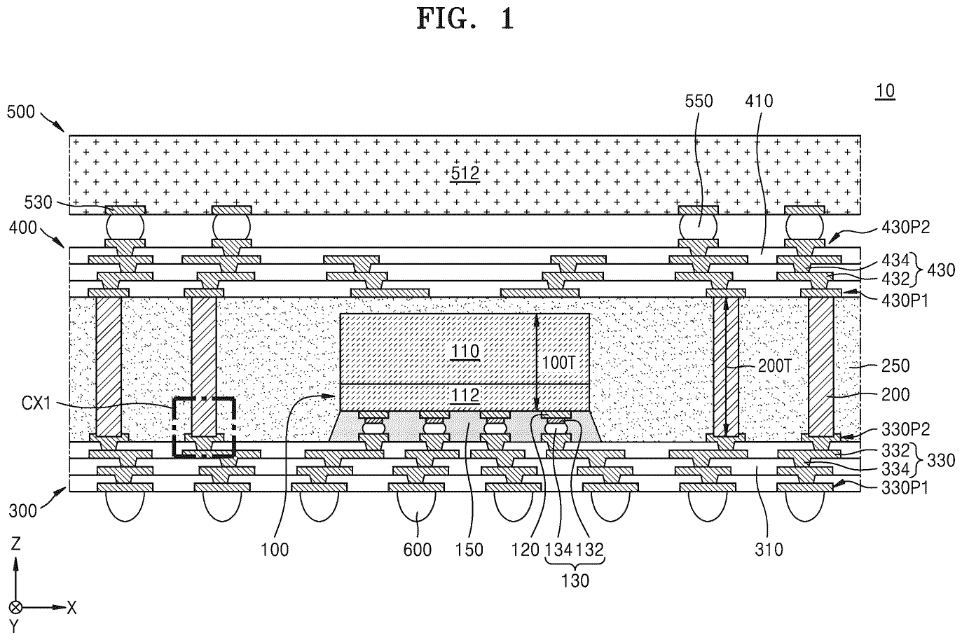

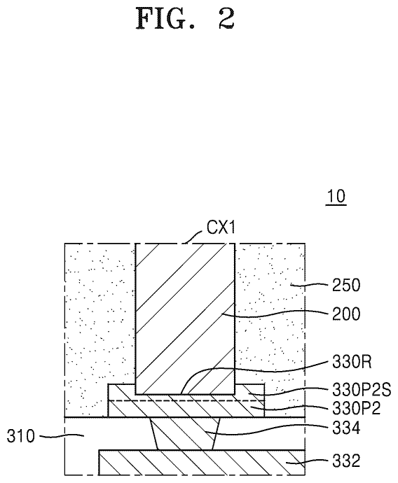

FIG. 1 is a cross-sectional view illustrating main elements of a semiconductor package 10 according to an example embodiment. FIG. 2 is an enlarged cross-sectional view of a region CX1 of FIG. 1.

Referring to FIGS. 1 and 2, the semiconductor package 10 may include a first semiconductor chip 100, a conductive post 200 disposed on the periphery of the first semiconductor chip 100, a first wiring structure 300 disposed under the first semiconductor chip 100, a second wiring structure 400 disposed on the first semiconductor chip 100, and a second semiconductor chip 500 disposed on the second wiring structure 400.

The semiconductor package 10 may have a package on package (PoP) structure. For example, the semiconductor package 10 may be a fan-out semiconductor package where a horizontal width and a horizontal area of the first wiring structure 300 are greater than a horizontal width and a horizontal area of the first semiconductor chip 100. In some example embodiments, the semiconductor package 10 may be a fan-out wafer level package (FOWLP) or a fan-out panel level package (FOPLP).

In some example embodiments, the first wiring structure 300 and the second wiring structure 400 may be formed by a redistribution process. Therefore, the first wiring structure 300 and the second wiring structure 400 may be referred to as a first redistribution structure and a second redistribution structure, respectively, or may be referred to as a lower redistribution structure and an upper redistribution structure, respectively.

The first wiring structure 300 may include a first redistribution insulation layer 310 and a plurality of first redistribution patterns 330. The first redistribution insulation layer 310 may surround the plurality of first redistribution patterns 330. In some example embodiments, the first wiring structure 300 may include a plurality of first redistribution insulation layers 310. The first redistribution insulation layer 310 may include, for example, a photo imageable dielectric (PID) or photosensitive polyimide (PSPI).

The plurality of first redistribution patterns 330 may include a plurality of first redistribution line patterns 332 and a plurality of first redistribution vias 334. The plurality of first redistribution patterns 330 may include, for example, metal such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), ruthenium (Ru), or an alloy thereof, but are not limited thereto.

The plurality of first redistribution line patterns 332 may be disposed on at least one of an upper surface and a lower surface of the first redistribution insulation layer 310. For example, when the first wiring structure 300 includes the plurality of first redistribution insulation layers 310 which are stacked, the plurality of first redistribution line patterns 332 may be disposed between an upper surface of an uppermost first redistribution insulation layer 310, a lower surface of a lowermost first redistribution insulation layer 310, and an adjacent first redistribution insulation layer 310.

The plurality of first redistribution vias 334 may pass through the first redistribution insulation layer 310 and may be connected to corresponding ones of the plurality of first redistribution line patterns 332. In some example embodiments, the plurality of first redistribution vias 334 may have a tapered shape where a horizontal width increases and extends from a lower side to an upper side.

In some example embodiments, some of the plurality of first redistribution line patterns 332 may be formed along with some of the plurality of first redistribution vias 334 to configure one body (e.g., one integral body). For example, the first redistribution line pattern 332 and the first redistribution via 334 contacting a lower surface of the first redistribution line pattern 332 may be formed together to configure one body.

The first redistribution patterns disposed adjacent to a lower surface of the first wiring structure 300 from among the plurality of first redistribution patterns 330 may be referred to as a plurality of first lower connection pads 330P1, and the first redistribution patterns disposed adjacent to an upper surface of the first wiring structure 300 from among the plurality of first redistribution patterns 330 may be referred to as a plurality of first upper connection pads 330P2. That is, the plurality of first lower connection pads 330P1 may be the first redistribution line patterns disposed adjacent to the lower surface of the first wiring structure 300 from among the plurality of first redistribution line patterns 332, and the plurality of first upper connection pads 330P2 may be the first redistribution patterns disposed adjacent to the upper surface of the first wiring structure 300 of from among the plurality of first redistribution line patterns 332.

A plurality of external connection terminals 600 may be attached on the plurality of first lower connection pads 330P1. The plurality of external connection terminals 600 may connect the semiconductor package 10 to the outside. In some example embodiments, each of the plurality of external connection terminals 600 may be a solder bump or a solder ball. Here, a plurality of chip connection members 130 may be attached to corresponding ones of the plurality of first upper connection pads 330P2, and a plurality of conductive posts 200 may be attached to other corresponding ones of the plurality of first upper connection pads 330P2.

The plurality of first upper connection pads 330P2 may be disposed on an upper surface of the first redistribution insulation layer 310. For example, when the first wiring structure 300 includes the plurality of first redistribution insulation layers 310 which are stacked, the plurality of first upper connection pads 330P2 may be disposed on the upper surface of the uppermost first redistribution insulation layer 310.

A plurality of metal seed layers 330P2S may be formed on the plurality of first upper connection pads 330P2 on which the plurality of conductive posts 200 are attached. For example, the plurality of first upper connection pads 330P2 may have a metal stack structure where a nickel (Ni) layer and a gold (Au) layer are sequentially formed on a Cu layer, and the plurality of metal seed layers 330P2S may have a metal stack structure where a Cu layer is formed on a Ti layer. For convenience of understanding, a case where a metal seed layer 330P2S is included in each of the plurality of first upper connection pads 330P2 may be described.

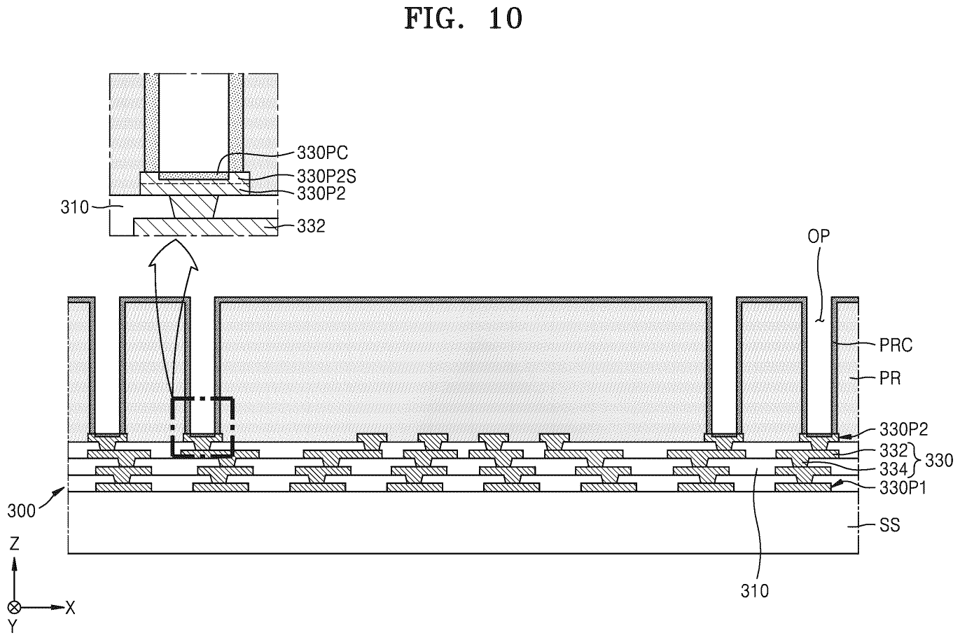

In the semiconductor package 10 according to an example embodiment, a recess region 330R may be formed in a surface of each of the plurality of first upper connection pads 330P2 on which the plurality of conductive posts 200 are attached. Although described below, the recess region 330R may be a portion, from which an impurity implantation layer 330PC (see FIG. 10) is removed, of each of the plurality of first upper connection pads 330P2.

At least one first semiconductor chip 100 may be mounted on the first wiring structure 300. The first semiconductor chip 100 may be provided as one or in plurality. The first semiconductor chip 100 may include a semiconductor substrate 110 including an active surface and an inactive surface opposite to each other, a semiconductor device 112 formed on the active surface of the semiconductor substrate 110, and a plurality of chip pads 120 disposed on a first surface of the first semiconductor chip 100. For example, the first semiconductor chip 100 may have a thickness 100T of about 150 μm or more.

Here, the first surface and a second surface of the first semiconductor chip 100 may be opposite to each other, and the second surface of the first semiconductor chip 100 may denote the inactive surface of the semiconductor substrate 110. The active surface of the semiconductor substrate 110 may be adjacent to the first surface of the first semiconductor chip 100, and thus, the illustration where the active surface of the semiconductor substrate 110 is differentiated from the first surface of the first semiconductor chip 100 is omitted.

In some example embodiments, the first semiconductor chip 100 may have face-down placement where the first surface of the first semiconductor chip 100 faces the first wiring structure 300 and may be mounted on an upper surface of the first wiring structure 300. In this case, the first surface of the first semiconductor chip 100 may be referred to as a lower surface of the first semiconductor chip 100, and the second surface of the first semiconductor chip 100 may be referred to as an upper surface of the first semiconductor chip 100.

A plurality of chip connection members 130 may be disposed between the plurality of chip pads 120 of the first semiconductor chip 100 and corresponding ones of the plurality of first upper connection pads 330P2 of the first wiring structure 300. For example, each of the plurality of chip connection members 130 may be a solder ball or a micro-bump. The first semiconductor chip 100 may be electrically connected to the first redistribution pattern 330 of the first wiring structure 300 through the plurality of chip connection members 130. The plurality of chip connection members 130 may include an under bump metal (UBM) layer 132 disposed on the plurality of chip pads 120 and a conductive connection member 134 covering the UBM layer 132. The plurality of chip connection members 130 may include, for example, Cu, Al, silver (Ag), Tin, Au, or a solder, but are not limited thereto.

The semiconductor substrate 110 may include, for example, a semiconductor material such as silicon (Si) or germanium (Ge). In some example embodiments, the semiconductor substrate 110 may include a compound semiconductor material such as silicon carbide (SiC), gallium arsenide (GaAs), indium arsenide (InAs), or indium phosphide (InP). The semiconductor substrate 110 may include an impurity-doped well which is a conductive region. The semiconductor substrate 110 may have various device isolation structures such as a shallow trench isolation (STI) structure.

The semiconductor device 112 including various kinds of a plurality of individual devices may be formed on the active surface of the semiconductor substrate 110. The plurality of individual devices may be electrically connected to the conductive region of the semiconductor substrate 110. The semiconductor device 112 may further include a conductive wiring or a conductive plug, which electrically connects the plurality of individual devices to the conductive region of the semiconductor substrate 110. Also, each of the plurality of individual devices may be electrically disconnected from the other individual device adjacent thereto by using an insulation layer.

In some example embodiments, the first semiconductor chip 100 may include a logic device. For example, the first semiconductor chip 100 may be a central processing unit (CPU) chip, a graphics processing unit (GPU) chip, or an application processor (AP) chip. In other example embodiments, when the semiconductor package 10 includes a plurality of first semiconductor chips 100, one of the plurality of first semiconductor chips 100 may be a CPU chip, a GPU chip, or an AP chip, and the other thereof may be a memory semiconductor chip including a memory device.

For example, the memory device may be a non-volatile memory device such as flash memory, phase-change random access memory (PRAM), magnetoresistive random access memory (MRAM), ferroelectric random access memory (FeRAM), or resistive random access memory (RRAM). In some example embodiments, the memory device may be a volatile memory chip such as dynamic random access memory (DRAM) or static random access memory (SRAM).

The second wiring structure 400 may include a second redistribution insulation layer 410 and a plurality of second redistribution patterns 430. The second redistribution insulation layer 410 may surround the plurality of second redistribution patterns 430. The second redistribution insulation layer 410 may include, for example, PID or photosensitive polyimide.

In some example embodiments, the second wiring structure 400 may include a plurality of second redistribution insulation layers 410. The plurality of second redistribution patterns 430 may include a plurality of second redistribution line patterns 432 and a plurality of second redistribution vias 434. The plurality of second redistribution patterns 430 may include metal or an alloy of metals. In some example embodiments, the plurality of second redistribution patterns 430 may be formed by stacking metal or an alloy of metals on a seed layer.

The plurality of second redistribution line patterns 432 may be disposed on at least one of an upper surface and a lower surface of the second redistribution insulation layer 410. For example, when the second wiring structure 400 includes the plurality of second redistribution insulation layers 410 which are stacked, the plurality of second redistribution line patterns 432 may be disposed between an upper surface of an uppermost second redistribution insulation layer 410, a lower surface of a lowermost second redistribution insulation layer 410, and an adjacent second redistribution insulation layer 410.

The second redistribution patterns disposed adjacent to a lower surface of the second wiring structure 400 from among the plurality of second redistribution patterns 430 may be referred to as a plurality of second lower connection pads 430P1, and the second redistribution patterns disposed adjacent to an upper surface of the second wiring structure 400 from among the plurality of second redistribution patterns 430 may be referred to as a plurality of second upper connection pads 430P2. For example, the plurality of second lower connection pads 430P1 may be the second redistribution patterns disposed adjacent to the lower surface of the second wiring structure 400 from among the plurality of second redistribution line patterns 432, and the plurality of second upper connection pads 430P2 may be the second redistribution patterns disposed adjacent to the upper surface of the second wiring structure 400 from among the plurality of second redistribution line patterns 432. In other example embodiments, the plurality of second lower connection pads 430P1 may be the second redistribution vias disposed adjacent to the second wiring structure 400 from among the plurality of second redistribution vias 434.

The second semiconductor chip 500 may include a second semiconductor device 512 and a plurality of second pads 530. The second semiconductor chip 500 may be electrically connected to the second wiring structure 400 by a plurality of internal connection terminals 550 disposed between the plurality of second pads 530 and the plurality of second upper connection pads 430P2. The second semiconductor chip 500 may be mounted on the second wiring structure 400 so that the plurality of second pads 530 face the second wiring structure 400.

In some example embodiments, the second semiconductor chip 500 may be electrically connected to the plurality of first redistribution patterns 330 of the first wiring structure 300 through the plurality of internal connection terminals 550 attached on the plurality of second pads 530, the plurality of second redistribution patterns 430, and the plurality of conductive posts 200.

In some example embodiments, the second semiconductor device 512 may be a memory device. For example, the memory device may be a non-volatile memory device such as flash memory, PRAM, MRAM, FeRAM, or RRAM. In some example embodiments, the memory device may be a volatile memory device such as DRAM or SRAM.

The plurality of second lower connection pads 430P1 may be disposed on a lower surface of the second redistribution insulation layer 410. For example, when the second wiring structure 400 includes the plurality of second redistribution insulation layers 410 which are stacked, the plurality of second lower connection pads 430P1 may be disposed on the lower surface of the lowermost second redistribution insulation layer 410.

The plurality of second upper connection pads 430P2 may be disposed on an upper surface of the second redistribution insulation layer 410. For example, when the second wiring structure 400 includes the plurality of second redistribution insulation layers 410 which are stacked, the plurality of second upper connection pads 430P2 may be disposed on the upper surface of the uppermost second redistribution insulation layer 410.

The plurality of second redistribution vias 434 may pass through the second redistribution insulation layer 410 and may contact and be connected to some of the plurality of second redistribution line patterns 432. In some example embodiments, some of the plurality of second redistribution line patterns 432 may be formed along with some of the plurality of second redistribution vias 434 to configure one body (e.g., one integral body). For example, the second redistribution line pattern 432 and the second redistribution via 434 contacting a lower surface of the second redistribution line pattern 432 may be formed together to configure one body.

In some example embodiments, the plurality of second redistribution vias 434 may have a tapered shape where a horizontal width narrows and extends from an upper side to a lower side. That is, the plurality of first redistribution vias 334 and the plurality of second redistribution vias 434 may extend in the same direction and may each have a horizontal width which narrows downward, but are not limited thereto.

Here, the first redistribution insulation layer 310, the first redistribution pattern 330, the first redistribution line pattern 332, and the first redistribution via 334 may be referred to as a first insulation layer, a first wiring pattern, a first wiring line pattern, and a first wiring via, respectively. Also, the second redistribution insulation layer 410, the second redistribution pattern 430, the second redistribution line pattern 432, and the second redistribution via 434 may be referred to as a second insulation layer, a second wiring pattern, a second wiring line pattern, and a second wiring via, respectively.

An encapsulant 250 may surround the first semiconductor chip 100, on an upper surface of the first wiring structure 300. The encapsulant 250 may fill a space between the first wiring structure 300 and the second wiring structure 400. For example, the encapsulant 250 may have a thickness of about 150 μm or about 500 μm. For example, the encapsulant 250 may be a molding member which includes an epoxy mold compound (EMC). The encapsulant 250 may further include a filler.

In some example embodiments, an underfill layer 150 surrounding the plurality of chip connection members 130 may be disposed between the first semiconductor chip 100 and the first wiring structure 300. In some example embodiments, the underfill layer 150 may fill a space between the first semiconductor chip 100 and the first wiring structure 300 and may cover a portion of a lower side of a side surface of the first semiconductor chip 100. The under-fill layer 150 may be formed by, for example, a capillary underfill process and may include epoxy resin.

In some example embodiments, a side surface of the first wiring structure 300, a side surface of the encapsulant 250, and a side surface of the second wiring structure 400 may be aligned with one another in a vertical direction and may be coplanar.

The plurality of conductive posts 200 may pass through the encapsulant 250 may electrically connect the first wiring structure 300 to the second wiring structure 400. The encapsulant 250 may surround the plurality of conductive posts 200.

The plurality of conductive posts 200 may be disposed between the first wiring structure 300 and the second wiring structure 400 so as to be apart from the first semiconductor chip 100 in a horizontal direction. For example, the plurality of conductive posts 200 may be apart from the first semiconductor chip 100 in the horizontal direction and may be disposed around the first semiconductor chip 100, in an outer region of the first wiring structure 300.

The plurality of conductive posts 200 may be disposed between the plurality of first upper connection pads 330P2 and the plurality of second lower connection pads 430P1. Lower surfaces of the plurality of conductive posts 200 may contact the plurality of first upper connection pads 330P2 of the first wiring structure 300 and may be electrically connected to the plurality of first redistribution patterns 330, and upper surfaces of the plurality of conductive posts 200 may contact the plurality of second lower connection pads 430P1 of the second wiring structure 400 and may be electrically connected to the plurality of second redistribution patterns 430.

In the semiconductor package 10 according to an example embodiment, the plurality of conductive posts 200 may fill the recess regions 330R of the plurality of first upper connection pads 330P2, and thus, levels of uppermost surfaces of the plurality of first upper connection pads 330P2 may be higher than levels of lower surfaces of the plurality of conductive posts 200 and levels of lowermost surfaces of the plurality of first upper connection pads 330P2 may be lower than the levels of the lower surfaces of the plurality of conductive posts 200.

In some example embodiments, a thickness 200T of each of the plurality of conductive posts 200 may be about 300 μm to about 500 μm, and a horizontal width of each of the plurality of conductive posts 200 may be about 120 μm to about 200 μm. In some example embodiments, the plurality of conductive posts 200 may include Cu or a Cu alloy, but are not limited thereto.

In some example embodiments, a horizontal width and a horizontal area of the first upper connection pad 330P2 contacting the conductive post 200 may be greater than a horizontal width and a horizontal area of the conductive post 200. For example, an entire lower surface of the conductive post 200 may contact an upper surface of the first upper connection pad 330P2, and a portion of the upper surface of the first upper connection pad 330P2 may not contact the conductive post 200.

In some example embodiments, a horizontal width and a horizontal area of the second lower connection pad 430P1 contacting the conductive post 200 may be greater than a horizontal width and a horizontal area of the conductive post 200. For example, an entire upper surface of the conductive post 200 may contact a lower surface of the second lower connection pad 430P1, and a portion of the lower surface of the second lower connection pad 430P1 may not contact the conductive post 200.

As the electronics industry advances rapidly and the demands of users increases, electronic devices are being miniaturized further, becoming more multifunctional, and have a larger capacity, and thus, highly-integrated semiconductor chips are needed. Accordingly, a thickness 100T of the first semiconductor chip 100 may progressively increase for enhancing a heat dissipation characteristic of the first semiconductor chip 100. As described above, an increase in thickness 100T of the first semiconductor chip 100 may affect the thickness 200T of each of the plurality of conductive posts 200 which electrically connect the first wiring structure 300 to the second wiring structure 400.

Generally, an exposure process and a development process each using a photoresist may be used for forming a conductive post. As a height of a conductive post increases rapidly, a thickness of a photoresist needs to be increased. Therefore, a post development baking (PDB) process of applying heat to a lower portion of a photoresist via a supporting substrate may be performed by using a curing process of maintaining a shape of a thickness-increased photoresist. However, in the PDB process, heat may be transferred from a lower portion of a photoresist, and thus, the degree of curing of the lower portion of the photoresist may be greater than the degree of curing of an upper portion of the photoresist. Accordingly, after a plating process of forming a conductive post is performed, the level of difficulty of a process of stripping the photoresist may increase, and a stripping time may be long consumed. Also, a problem where a residual material of a cured photoresist remains on a wiring structure may occur.

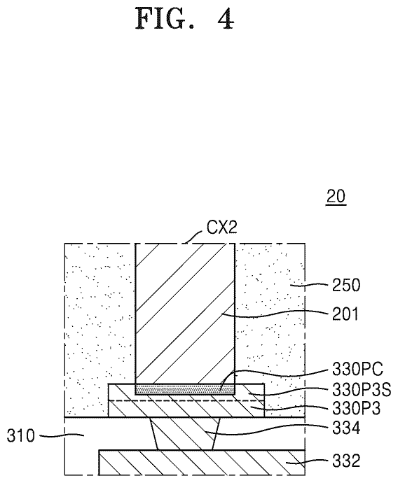

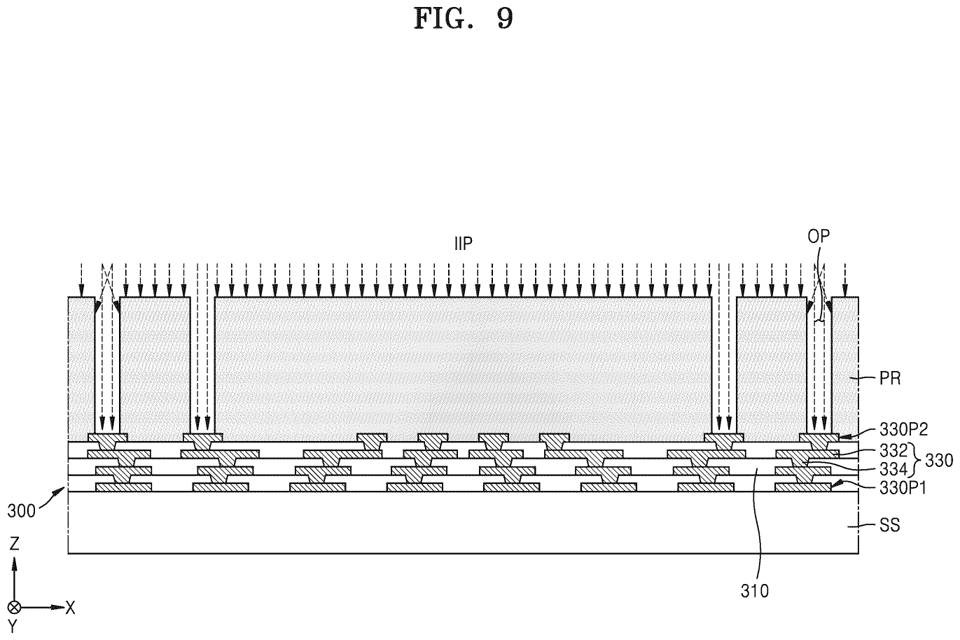

To solve such a problem, in the semiconductor package 10 according to an example embodiment, the degree of curing of a surface from an upper portion of a photoresist (see PR of FIG. 9) may increase through an ion implantation process (see IIP of FIG. 9), based on a below-described method of manufacturing a semiconductor package (see S10 of FIG. 4). Therefore, a phenomenon where compositions of the photoresist PR (see FIG. 9) are eluted to a plating solution in the plating process may decrease, and moreover, a residual material of a cured photoresist PR (see FIG. 9) may be easily removed from the first wiring structure 300.

Thus, the semiconductor package 10 according to an example embodiment, the ion implantation process (see IIP of FIG. 9) may be used as a curing process of maintaining a shape of a thickness-increased photoresist PR (see FIG. 9), instead of the PDB process, and thus, the reliability and productivity of the semiconductor package 10 may be enhanced.

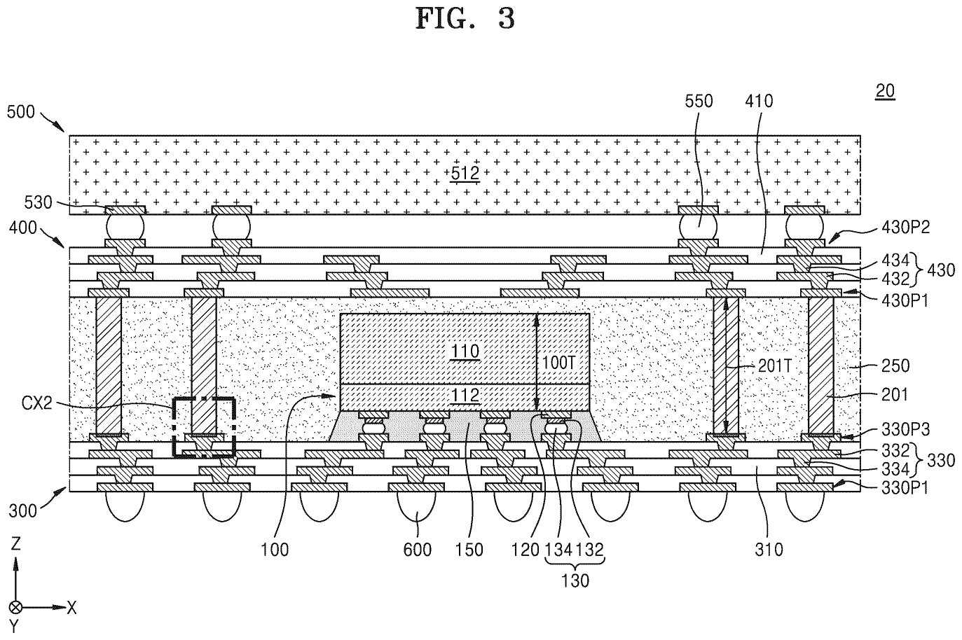

FIG. 3 is a cross-sectional view illustrating main elements of a semiconductor package 20 according to an example embodiment. FIG. 4 is an enlarged cross-sectional view of a region CX2 of FIG. 3.

Most elements configuring the semiconductor package 20 described below and materials of the elements may be substantially the same as the descriptions of FIGS. 1 and 2. Therefore, for convenience of description, a difference with the semiconductor package 10 described above will be mainly described below.

Referring to FIGS. 3 and 4, the semiconductor package 20 may include a first semiconductor chip 100, a conductive post 201 disposed on the periphery of the first semiconductor chip 100, a first wiring structure 300 disposed under the first semiconductor chip 100, a second wiring structure 400 disposed on the first semiconductor chip 100, and a second semiconductor chip 500 disposed on the second wiring structure 400.

The first redistribution patterns disposed adjacent to a lower surface of the first wiring structure 300 from among the plurality of first redistribution patterns 330 may be referred to as a plurality of first lower connection pads 330P1, and the first redistribution patterns disposed adjacent to an upper surface of the first wiring structure 300 from among the plurality of first redistribution patterns 330 may be referred to as a plurality of first upper connection pads 330P3. That is, the plurality of first lower connection pads 330P1 may be the first redistribution line patterns disposed adjacent to the lower surface of the first wiring structure 300 from among the plurality of first redistribution line patterns 332, and the plurality of first upper connection pads 330P3 may be the first redistribution line patterns disposed adjacent to the upper surface of the first wiring structure 300 from among the plurality of first redistribution line patterns 332.

A plurality of external connection terminals 600 may be attached on the plurality of first lower connection pads 330P1. The plurality of external connection terminals 600 may connect the semiconductor package 20 to the outside. In some example embodiments, each of the plurality of external connection terminals 600 may be a solder bump or a solder ball. On the other hand, a plurality of chip connection members 130 may be attached to corresponding ones of the plurality of first upper connection pads 330P3, and a plurality of conductive posts 201 may be attached on other corresponding ones of the plurality of first upper connection pads 330P3.

The plurality of first upper connection pads 330P3 may be disposed on an upper surface of the first redistribution insulation layer 310. For example, when the first wiring structure 300 includes the plurality of first redistribution insulation layers 310 which are stacked, the plurality of first upper connection pads 330P3 may be disposed on the upper surface of the uppermost first redistribution insulation layer 310.

A plurality of metal seed layers 330P3S may be formed on the plurality of first upper connection pads 330P3 on which the plurality of conductive posts 201 are attached. For example, the plurality of first upper connection pads 330P3 may have a metal stack structure where a Ni layer and an Au layer are sequentially formed on a Cu layer, and the plurality of metal seed layers 330P3S may have a metal stack structure where a Cu layer is formed on a Ti layer. For convenience of understanding, a case where the metal seed layer 330P3S is included in each of the plurality of first upper connection pads 330P3 may be described.

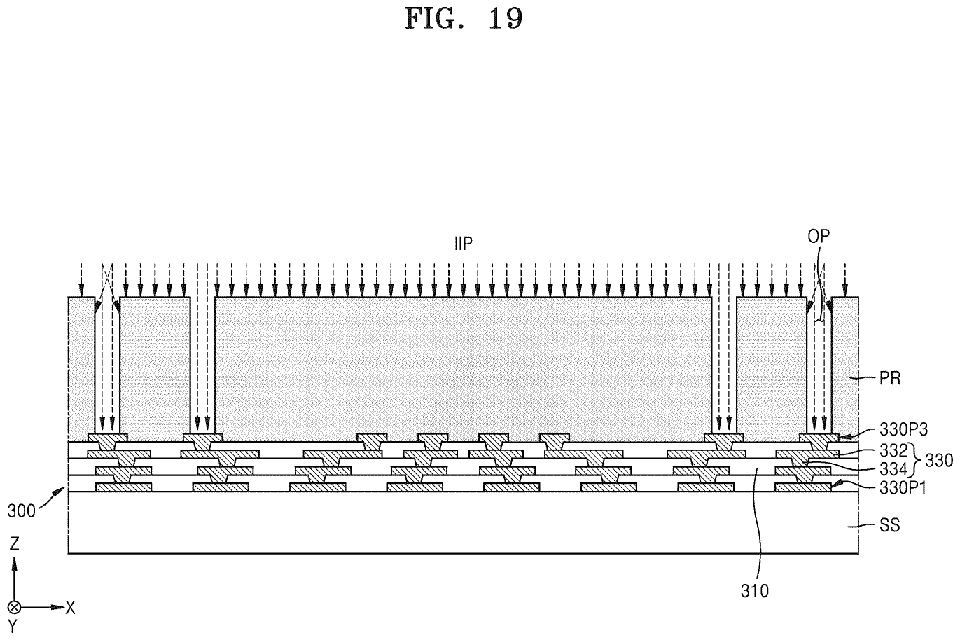

In the semiconductor package 20 according to an example embodiment, an impurity implantation layer 330PC may be formed on a surface of each of the plurality of first upper connection pads 330P3 on which the plurality of conductive posts 201 are attached. Although described below, the impurity implantation layer 330PC in the plurality of first upper connection pads 330P3 may be a region into which a trivalent ion (e.g., boron (B), gallium (Ga), or indium (In)) or a pentavalent ion (e.g., phosphorus (P), arsenic (As), antimony (Sb), or bismuth (Bi)) is implanted by an ion implantation (see IIP of FIG. 19) process.

In some example embodiments, the surface roughness of the impurity implantation layer 330PC may increase due to ion bombardment caused by ion implantation (see IIP of FIG. 19). Accordingly, in the plurality of first upper connection pads 330P3, the surface roughness of the impurity implantation layer 330PC may differ from the surface roughness of a peripheral region surrounding the impurity implantation layer 330PC.

In the semiconductor package 20 according to an example embodiment, the plurality of conductive posts 201 may be formed to directly contact the impurity implantation layer 330PC of the plurality of first upper connection pads 330P3, and thus, levels of uppermost surfaces of the plurality of first upper connection pads 330P3 may be substantially the same as levels of lower surfaces of the plurality of conductive posts 201.

In some example embodiments, a thickness 201T of each of the plurality of conductive posts 201 may be about 300 μm to about 500 μm, and a horizontal width of each of the plurality of conductive posts 201 may be about 120 μm to about 200 μm.

Thus, the semiconductor package 20 according to an example embodiment, the ion implantation process (see IIP of FIG. 19) may be used as a curing process of maintaining a shape of a thickness-increased photoresist PR (see FIG. 19), instead of the PDB process, and thus, the reliability and productivity of the semiconductor package 20 may be enhanced.

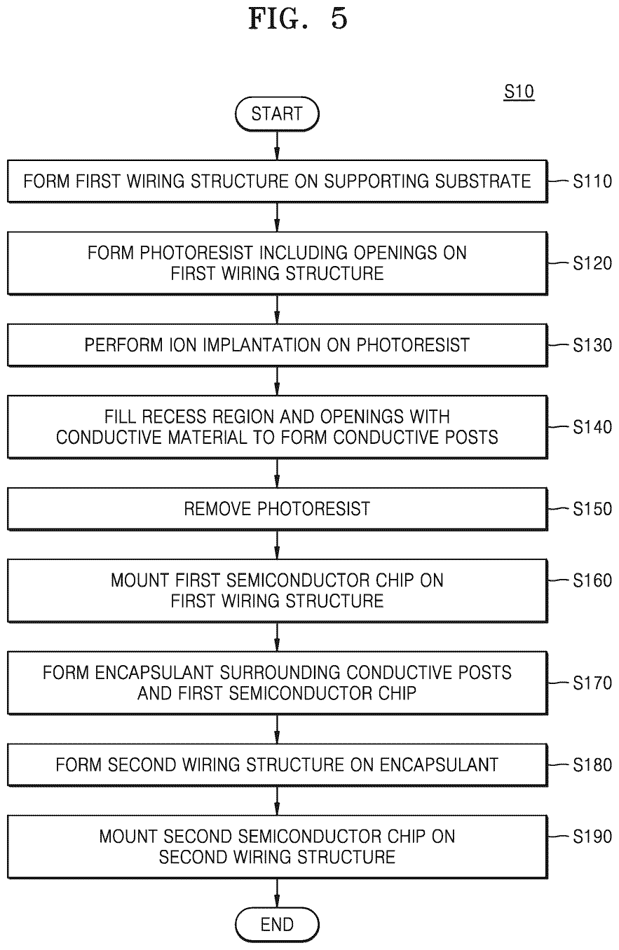

FIG. 5 is a flowchart illustrating a method of manufacturing a semiconductor package, according to an example embodiment.

Referring to FIG. 5, a method S10 of manufacturing a semiconductor package may include a process sequence of first to ninth operations S110 to S190.

In some embodiments, a certain process sequence may be executed unlike a described sequence. For example, two processes continuously described may be simultaneously performed, or may be performed in a sequence opposite to a described sequence.

The method S10 of manufacturing the semiconductor package according to an example embodiment may include first operation S110 of forming a first wiring structure on a supporting substrate, second operation S120 of forming a photoresist including a plurality of openings on the first wiring structure, third operation S130 of performing ion implantation into the photoresist, fourth operation S140 of filling a recess region and the plurality of openings with a conductive material to form a plurality of conductive posts, fifth operation S150 of removing the photoresist, sixth operation S160 of mounting a first semiconductor chip on the first wiring structure, seventh operation S170 of forming an encapsulant surrounding the first semiconductor chip and the plurality of conductive posts, eighth operation S180 of forming a second wiring structure on the encapsulant, and ninth operation S190 of mounting a second semiconductor chip on the second wiring structure.

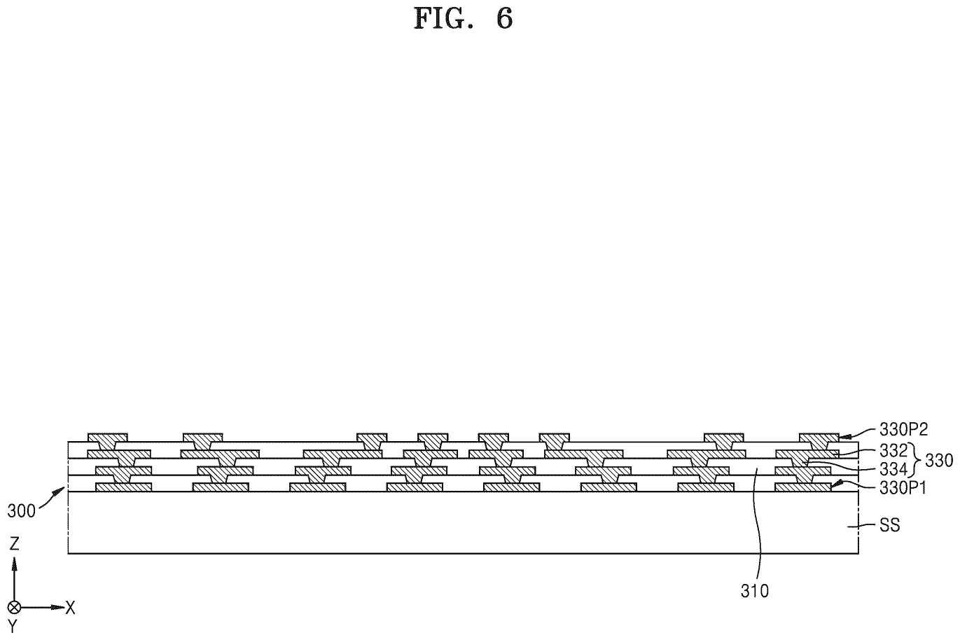

Each of first to ninth operations S110 to S190 will be described below with reference to FIGS. 6 to 17.

FIGS. 6 to 17 are diagrams illustrating in process sequence a method of manufacturing a semiconductor package, according to an example embodiment.

Referring to FIG. 6, a first wiring structure 300 which includes a first redistribution insulation layer 310 and a plurality of first redistribution patterns 330 including a plurality of first redistribution line patterns 332 and a plurality of first redistribution vias 334 may be formed on a supporting substrate SS.

The supporting substrate SS may be a semiconductor substrate, a glass substrate, a ceramic substrate, or a plastic substrate. In some example embodiments, a release film may be attached on the supporting substrate SS, and then the first wiring structure 300 may be formed thereon.

The plurality of first redistribution line patterns 332 may be formed on the supporting substrate SS. The first redistribution line patterns that are formed on (e.g., immediately on) the supporting substrate SS from among the plurality of first redistribution line patterns 332 may be referred to as a plurality of first lower connection pads 330P1.

Subsequently, a first preliminary redistribution insulation layer covering the first redistribution line pattern 332 may be formed on the supporting substrate SS, and then, the first redistribution insulation layer 310 including a plurality of first via holes may be formed by removing a portion of the first preliminary redistribution insulation layer through an exposure process and a development process. The plurality of first via holes may be formed so that a horizontal width thereof narrows toward a lower surface of the first redistribution insulation layer 310 from an upper surface of the first redistribution insulation layer 310. In some example embodiments, a plurality of first lower connection pads 330P1 and a lower surface of a lowermost first redistribution insulation layer 310 may be formed to be coplanar.

A first redistribution conductive layer may be formed on the first redistribution insulation layer 310, and then, the first redistribution pattern 330 including the first redistribution line pattern 332 and the first redistribution via 334 may be formed by patterning the first redistribution conductive layer. The first redistribution via 334 may be a portion, filling the plurality of first via holes, of the first redistribution pattern 330, and the first redistribution line pattern 332 may be a portion, which is upper than an upper surface of the first redistribution insulation layer 310, of the first redistribution pattern 330.

The first redistribution via 334 may be formed so that a horizontal width thereof narrows toward the lower surface of the first redistribution insulation layer 310 from the upper surface of the first redistribution insulation layer 310. The first redistribution pattern 330 including the first redistribution line pattern 332 and the first redistribution via 334 may be formed by patterning the first redistribution conductive layer, and thus, a portion of the first redistribution line pattern 332 formed on the first redistribution insulation layer 310, which include the plurality of first via holes, may configure one body with a portion of the first redistribution via 334.

Subsequently, the first wiring structure 300 may be formed by repeatedly forming the first redistribution insulation layer 310 and the first redistribution pattern 330. The first redistribution line pattern 332 disposed on an upper surface of the first wiring structure 300 from among the plurality of first redistribution line pattern 332 may be referred to as a plurality of first upper connection pads 330P2. In some example embodiments, when the first wiring structure 300 includes the plurality of first redistribution insulation layers 310 which are stacked, the plurality of first upper connection pads 330P2 may be the first redistribution line pattern 332 disposed on an upper surface of an uppermost first redistribution insulation layer 310.

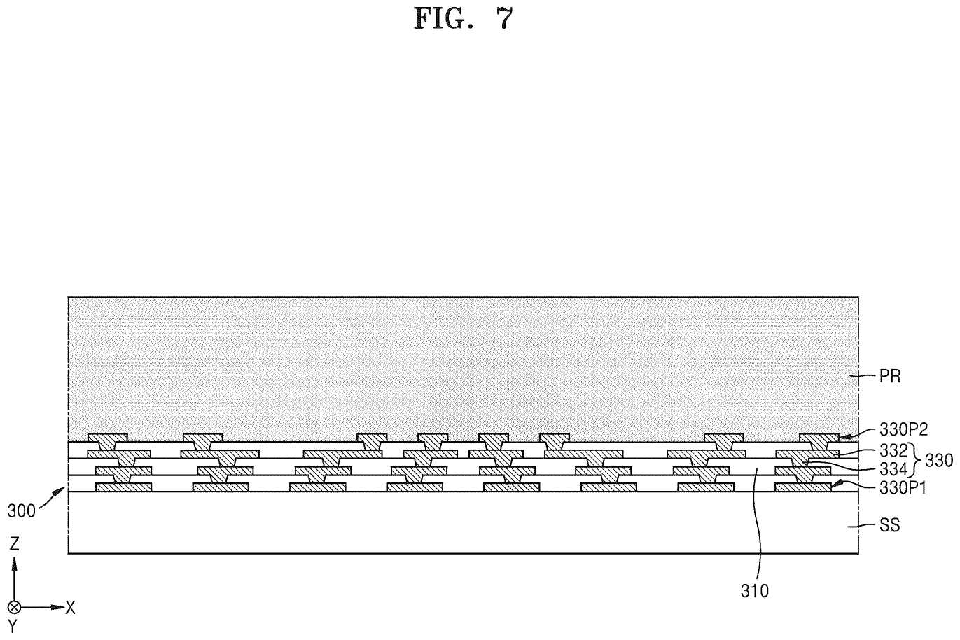

Referring to FIG. 7, a photoresist PR may be formed by coating and baking a photoresist solution on the first wiring structure 300.

In some example embodiments, the photoresist PR may be a negative-type photoresist. Generally, a negative-type photoresist used in negative tone development may use a chemical amplified photoresist material, of which an exposed portion (i.e., a portion on which a threshold or more amount of light is irradiated) may remain, and an unexposed portion (i.e., a portion on which a threshold or more amount of light is not irradiated) may be removed by a solvent.

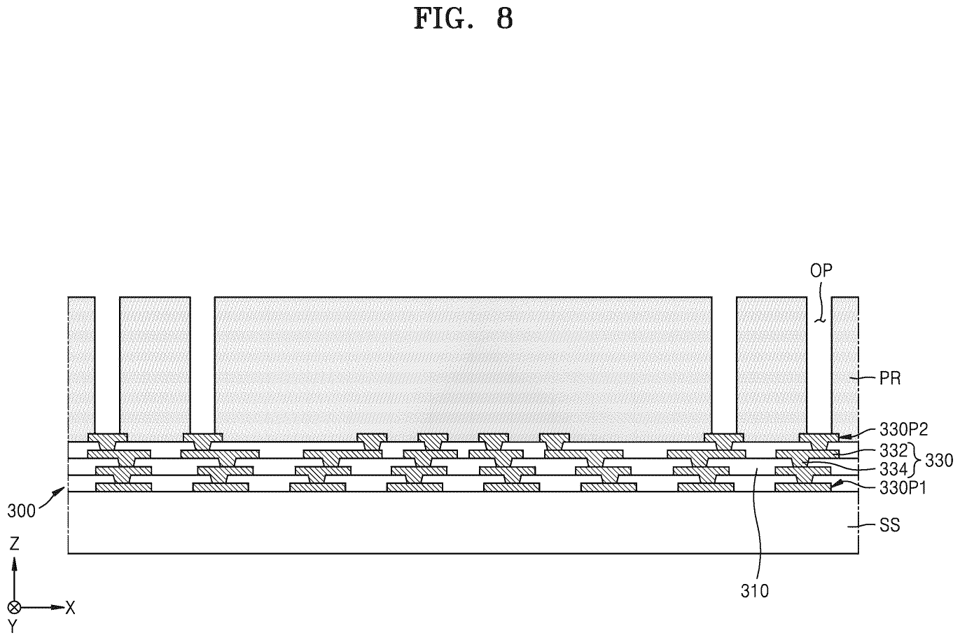

Referring to FIG. 8, by exposing and developing the photoresist PR, a plurality of openings OP may be formed in an outer region of the first wiring structure 300.

Based on an exposure process and a development process, the plurality of openings OP having a high aspect ratio may be regularly formed in the outer region of the first wiring structure 300. The plurality of openings OP may expose partial portions of upper surfaces of the plurality of first upper connection pads 330P2 disposed in the outer region of the first wiring structure 300, respectively. That is, the other portions of the upper surfaces of the plurality of first upper connection pads 330P2 disposed in the outer region of the first wiring structure 300 may be covered by the photoresist PR, and thus, may not be exposed.

Referring to FIG. 9, an ion implantation IIP process may be performed on an entire surface of the photoresist PR.

Based on the ion implantation IIP process, a trivalent ion (e.g., B, Ga, or In) or a pentavalent ion (e.g., P, As, Sb, or Bi) may be an impurity ion and may be implanted into an upper surface and a sidewall of the photoresist PR and surfaces of the plurality of first upper connection pads 330P2 exposed by the plurality of openings OP.

In some example embodiments, by adjusting output energy of the ion implantation IIP process, a process may be performed so that impurities are implanted into only a shallow surface of the photoresist PR and a shallow surface of the first upper connection pad 330P2.

Referring to FIG. 10, based on the ion implantation IIP (see FIG. 9) process, a surface curing layer PRC may be formed on the upper surface and the sidewall of the photoresist PR, and an impurity implantation layer 330PC may be formed on surfaces of the plurality of first upper connection pads 330P2 exposed by the plurality of openings OP.

The upper surface and the sidewall of the photoresist PR may be cured by ion bombardment based on ion implantation IIP (see FIG. 19). In some example embodiments, a total thickness of the photoresist PR may be about 300 μm to about 500 μm, and a thickness of the surface curing layer PRC may be about 0.3 μm to about 1 μm.

Here, the surface curing layer PRC may be a carbon-rich (C-rich) layer. This is not limited to a specific theory, but in various compositions constituting the photoresist PR, a carbon-carbon (C—C) bond may be relatively stronger than coupling energy of other atoms, and thus, based on the ion implantation IIP (see FIG. 19), other atoms may move to a portion under the photoresist PR relatively more than carbon (C). Accordingly, a content of carb(C) in the surface curing layer PRC of the photoresist PR may become relatively higher than the other portion of the photoresist PR.

Partial portions of the plurality of first upper connection pads 330P2 may be configured with a plurality of metal seed layers 330P2S. Therefore, the impurity implantation layer 330PC may be formed on a surface of the metal seed layer 330P2S in the plurality of first upper connection pads 330P2.

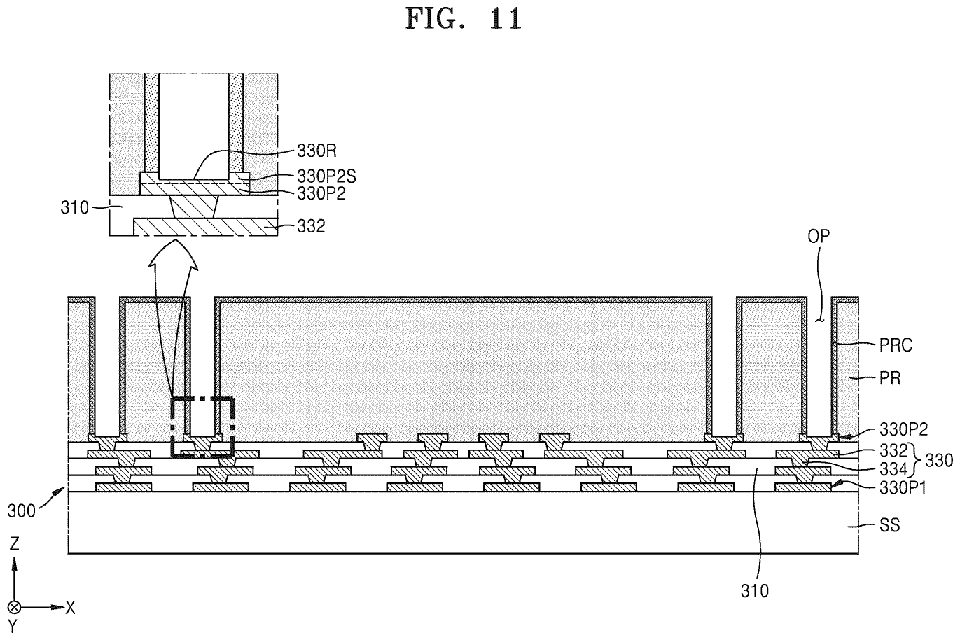

Referring to FIG. 11, a plating preprocessing process may be performed on a supporting substrate SS where the photoresist PR is formed.

The plating preprocessing process may include, for example, rinsing treatment and acid treatment. Here, by adjusting an acid concentration of a solution used in acid treatment, the surface curing layer PRC of the photoresist PR may remain, and the impurity implantation layer 330PC may be removed in the surface of each of the plurality of metal seed layers 330P2S. Therefore, a recess region 330R may be formed in the surface of each of the plurality of metal seed layers 330P2S exposed by the plurality of openings OP.

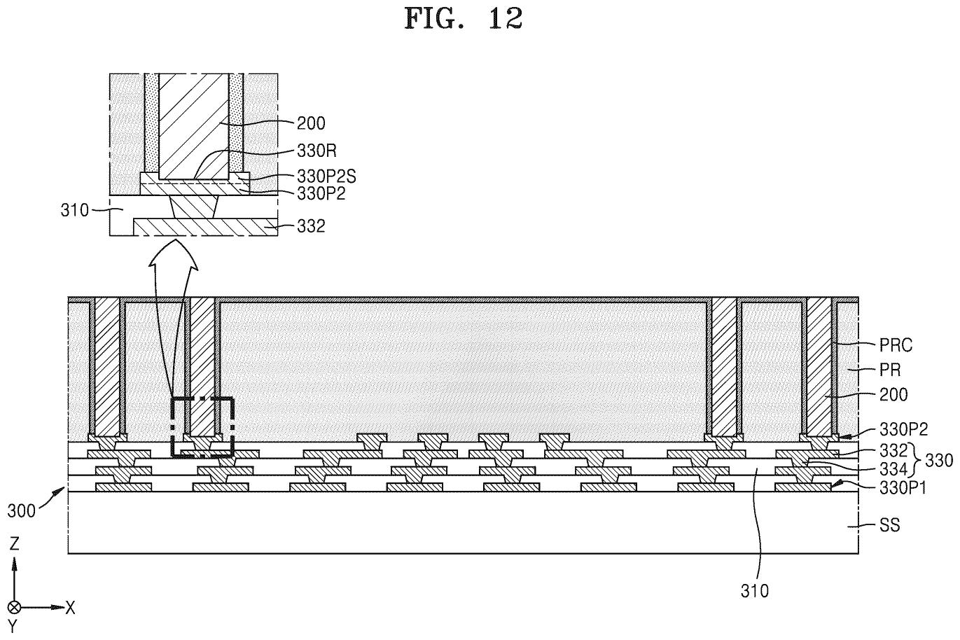

Referring to FIG. 12, a plurality of conductive posts 200 electrically connected to the plurality of first upper connection pads 330P2 disposed in an outer region may be formed by filling a conductive material in the plurality of openings OP (see FIG. 11) and the recess region 330R (see FIG. 11).

The plurality of conductive posts 200 may be formed by an electro-plating process. In some example embodiments, the plurality of conductive posts 200 satisfying a desired shape may be formed by a single plating process. For example, the conductive material may include Cu or a Cu alloy, but are not limited thereto.

For example, the plurality of metal seed layers 330P2S in the plurality of first upper connection pads 330P2 may function as a seed layer for forming the plurality of conductive posts 200. That is, in a case where the plurality of conductive posts 200 are formed by an electro-plating process, the plurality of metal seed layers 330P2S may provide a path which enables a current to flow, and thus, the plurality of conductive posts 200 may be formed up to the recess regions 330R (e.g., formed upward from the recess regions 330R) (see FIG. 11) of the plurality of first upper connection pads 330P2.

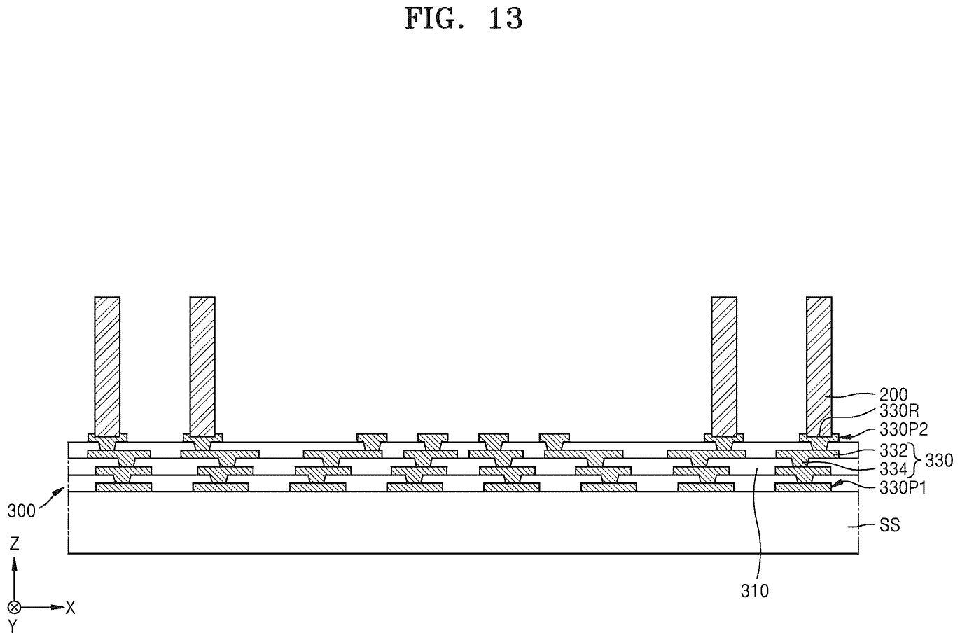

Referring to FIG. 13, after the plurality of conductive posts 200 are formed, the photoresist PR (see FIG. 12) may be removed.

A stripping process and/or an ashing process may be performed for removing the photoresist PR (see FIG. 12). As the photoresist PR (see FIG. 12) is removed, the plurality of conductive posts 200 may be disposed in an outer region of the first wiring structure 300.

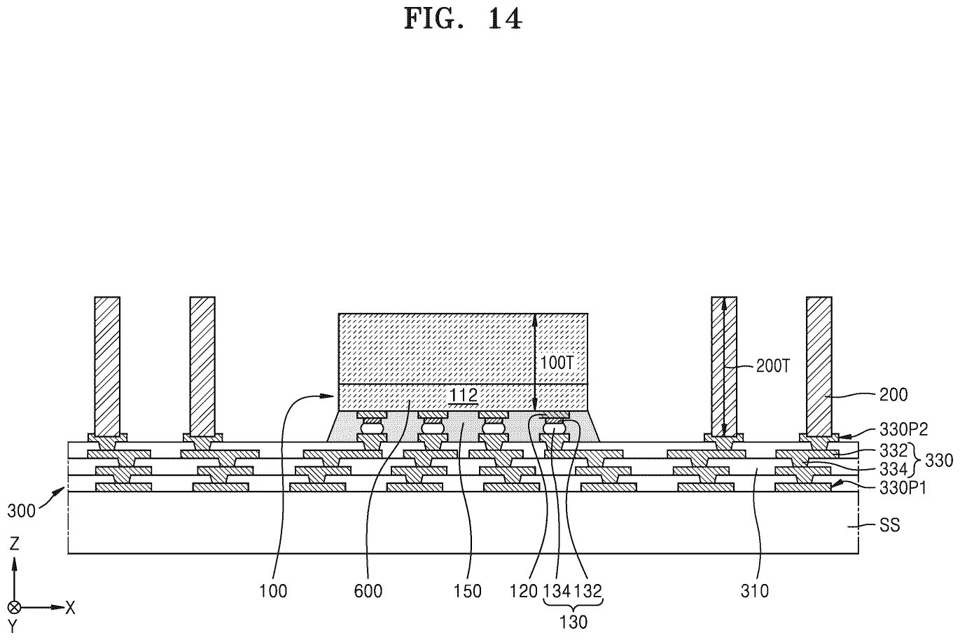

Referring to FIG. 14, a first semiconductor chip 100 including a plurality of chip pads 120 may be mounted on the first wiring structure 300.

The first semiconductor chip 100 may be mounted on the first wiring structure 300 so that a plurality of chip connection members 130 are disposed between the plurality of chip pads 120 and corresponding ones of the plurality of first upper connection pads 330P2 of the first wiring structure 300.

The first semiconductor chip 100 may be mounted on a chip mount region of the first wiring structure 300 so as to be apart from the plurality of conductive posts 200 in a horizontal direction. For example, the plurality of chip connection members 130 each including an UBM layer 132 and a conductive connection member 134 covering the UBM layer 132 may be formed on the plurality of chip pads 120 of the first semiconductor chip 100, and the first semiconductor chip 100 where the plurality of chip connection members 130 are formed may be mounted on the first wiring structure 300.

An underfill layer 150 may be formed to fill between the first semiconductor chip 100 and the first wiring structure 300. The underfill layer 150 may be formed to surround the plurality of chip connection members 130. In some example embodiments, the underfill layer 150 may be formed to fill a space between the first semiconductor chip 100 and the first wiring structure 300 and cover a portion of a lower side of a side surface of the first semiconductor chip 100.

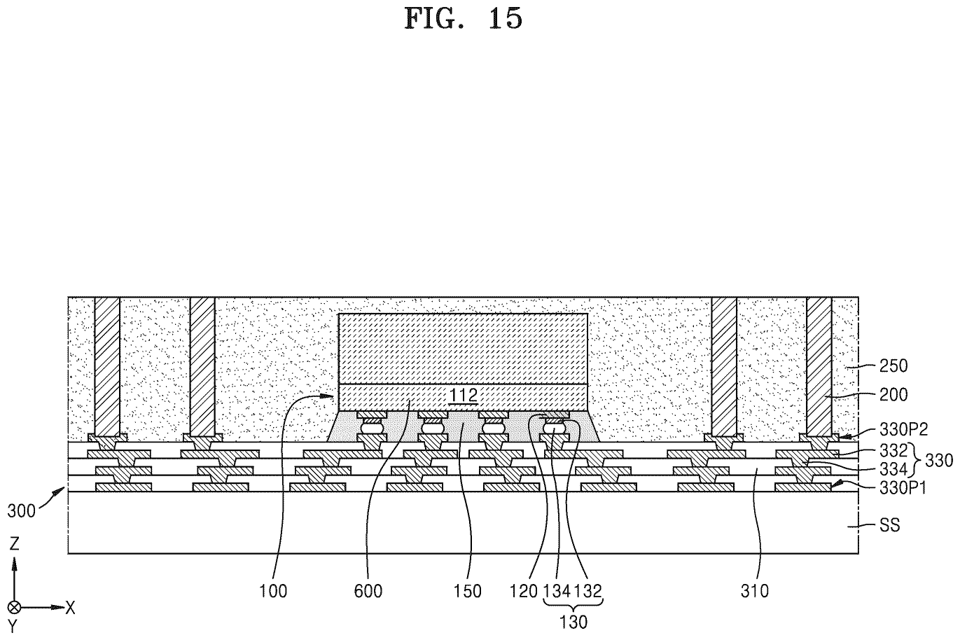

Referring to FIG. 15, an encapsulant 250 covering the first semiconductor chip 100 and the plurality of conductive posts 200 may be formed.

The encapsulant 250 may be formed to cover all of an upper surface of each of the plurality of conductive posts 200 and include an upper surface disposed at a vertical level which is higher than an uppermost end of the plurality of conductive posts 200.

Subsequently, a portion of the encapsulant 250 may be removed to expose the plurality of conductive posts 200. That is, a portion of an upper portion of the encapsulant 250 may be removed by a chemical mechanical polishing (CMP) process. The encapsulant 250 may include a molding member including an epoxy mold compound.

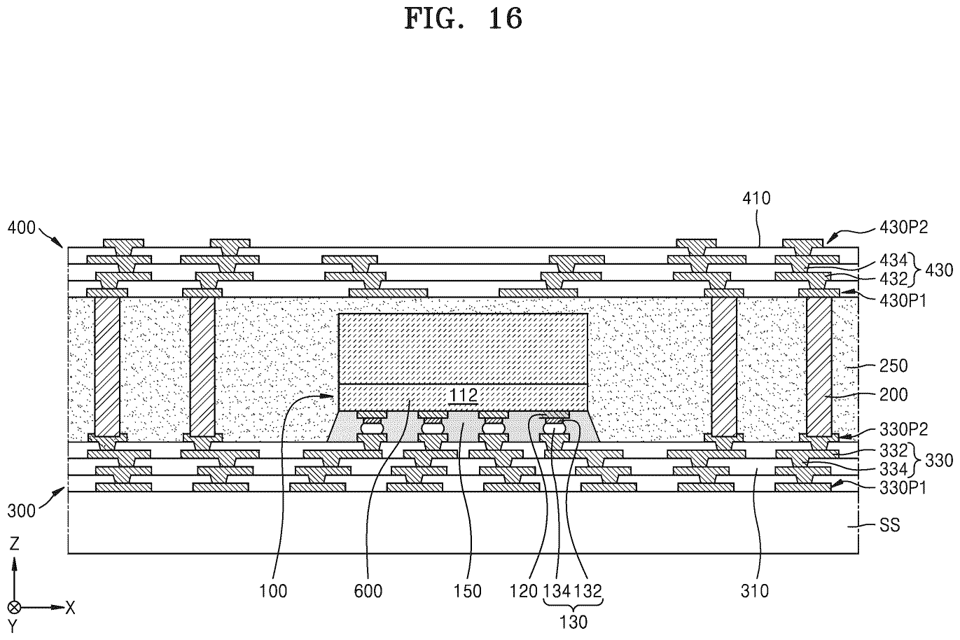

Referring to FIG. 16, a second wiring structure 400 which includes a second redistribution insulation layer 410 and a plurality of second redistribution patterns 430 including a plurality of second redistribution line patterns 432 and a plurality of second redistribution vias 434 may be formed on the plurality of conductive posts 200 and the encapsulant 250.

A second preliminary redistribution insulation layer may be formed on the plurality of conductive posts 200 and the encapsulant 250, and then, the second redistribution insulation layer 410 may be formed by removing a portion of the second preliminary redistribution insulation layer through an exposure process and a development process.

The plurality of second via holes may be formed so that a horizontal width thereof narrows toward a lower surface of the second redistribution insulation layer 410 from an upper surface of the second redistribution insulation layer 410. A second redistribution conductive layer may be formed on the second redistribution insulation layer 410, and then, the second redistribution pattern 430 including the second redistribution line pattern 432 and the second redistribution via 434 may be formed by patterning the second redistribution conductive layer.

The second redistribution vias 434 formed on the plurality of conductive posts 200 from among the plurality of second redistribution vias 343 may be referred to as a plurality of second lower connection pads 430P1. The second redistribution via 434 may be a portion, filling the plurality of second via holes, of the second redistribution pattern 430, and the second redistribution line pattern 432 may be a portion, which is upper than an upper surface of the second redistribution insulation layer 410, of the second redistribution pattern 430. The second redistribution via 434 may be formed so that a horizontal width thereof narrows toward the lower surface of the second redistribution insulation layer 410 from the upper surface of the second redistribution insulation layer 410. The second redistribution pattern 430 including the second redistribution line pattern 432 and the second redistribution via 434 may be formed by patterning the second redistribution conductive layer, and thus, a portion of the second redistribution line pattern 432 formed on the second redistribution insulation layer 410 including the plurality of second via holes may configure one body with a portion of the second redistribution via 434.

Subsequently, the second wiring structure 400 may be formed by repeatedly forming the second redistribution insulation layer 410 and the second redistribution pattern 430. In some example embodiments, a plurality of second lower connection pads 430P1 and a lower surface of a lowermost second redistribution insulation layer 410 may be formed to be coplanar.

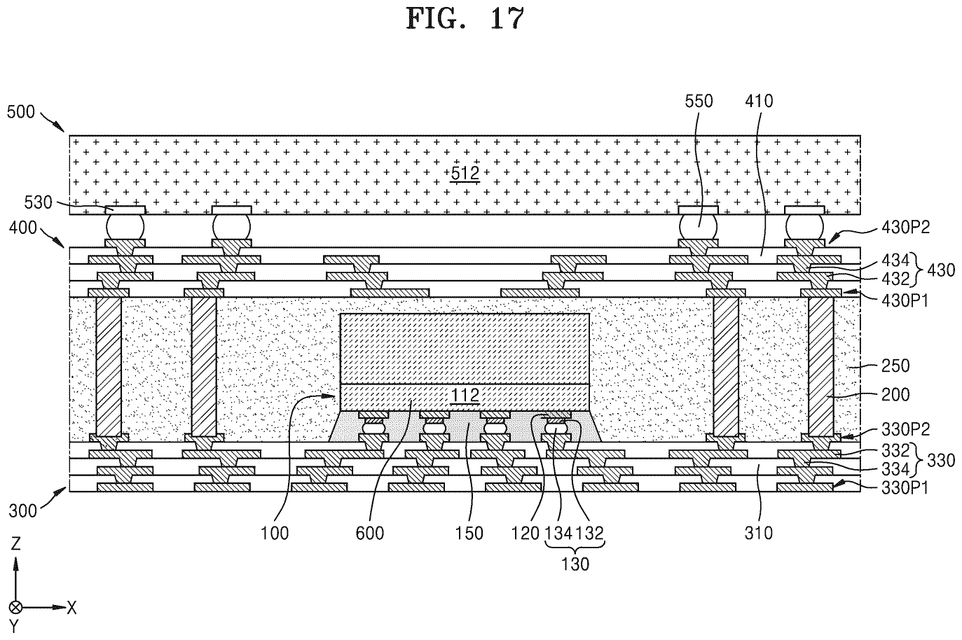

Referring to FIG. 17, a second semiconductor chip 500 may be mounted to be electrically connected to the second wiring structure 400.

The second semiconductor chip 500 may be mounted on the second wiring structure 400 so that the plurality of upper connection pads 530 face the second wiring structure 400.

In some example embodiments, the second semiconductor chip 500 may be electrically connected to the plurality of first redistribution patterns 330 of the first wiring structure 300 through the plurality of internal connection terminals 550 attached on the plurality of upper connection pads 530, the plurality of second redistribution patterns 430, and the plurality of conductive posts 200.

Referring again to FIG. 1, the semiconductor package 10 may be finished by attaching a plurality of external connection terminals 600 on the plurality of first lower connection pads 330P1.

As described above, in the method of manufacturing the semiconductor package 10 according to an example embodiment, the degree of curing of a surface of the photoresist PR may increase through the ion implantation IIP, and thus, a phenomenon where compositions of the photoresist PR are eluted to a plating solution in the plating process may decrease, and moreover, a residual material of a cured photoresist PR may be easily removed, thereby enhancing the reliability and productivity of the semiconductor package 10.

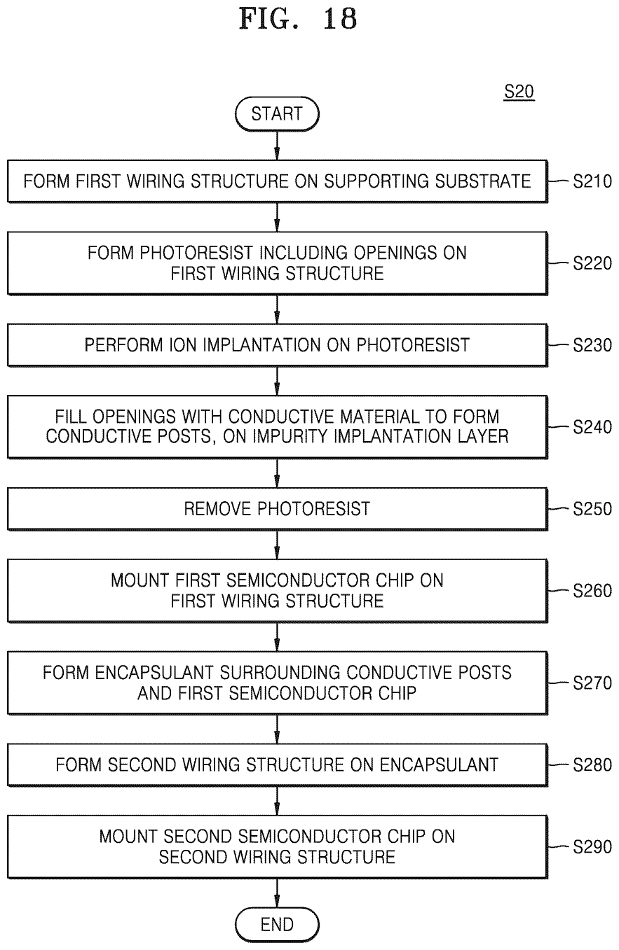

FIG. 18 is a flowchart illustrating a method of manufacturing a semiconductor package, according to an example embodiment.

Referring to FIG. 18, a method S20 of manufacturing a semiconductor package may include a process sequence of first to ninth operations S210 to S290.

In a case where some embodiments are differently implemented, a certain process sequence may be executed unlike a described sequence. For example, two processes continuously described may be simultaneously performed, or may be performed in a sequence opposite to a described sequence.

The method S20 of manufacturing the semiconductor package according to an example embodiment may include first operation S210 of forming a first wiring structure on a supporting substrate, second operation S220 of forming a photoresist including a plurality of openings on the first wiring structure, third operation S230 of performing ion implantation into the photoresist, fourth operation S240 of filling the plurality of openings with a conductive material on an impurity implantation layer to form a plurality of conductive posts, fifth operation S250 of removing the photoresist, sixth operation S260 of mounting a first semiconductor chip on the first wiring structure, seventh operation S270 of forming an encapsulant surrounding the first semiconductor chip and the plurality of conductive posts, eighth operation S280 of forming a second wiring structure on the encapsulant, and ninth operation S290 of mounting a second semiconductor chip on the second wiring structure.

Each of first to ninth operations S210 to S290 will be described below with reference to FIGS. 19 to 22.

FIGS. 19 to 22 are diagrams illustrating in process sequence a method of manufacturing a semiconductor package, according to an example embodiment.

A method of forming most elements, included in a method of manufacturing the semiconductor package 20 described below, may be substantially the same as or similar to the above descriptions of FIGS. 6 to 17. Therefore, for convenience of description, a difference with the method of manufacturing the semiconductor package 10 described above will be mainly described below.

Referring to FIG. 19, an ion implantation IIP process may be performed on an entire surface of the photoresist PR.

Based on the ion implantation IIP process, a trivalent ion or a pentavalent ion may be impurities and may be implanted into an upper surface and a sidewall of the photoresist PR and surfaces of a plurality of first upper connection pads 330P3 exposed by a plurality of openings OP.

By adjusting output energy of the ion implantation IIP process, a process may be performed so that impurities are implanted into only a shallow surface of the photoresist PR and a shallow surface of the first upper connection pad 330P3.

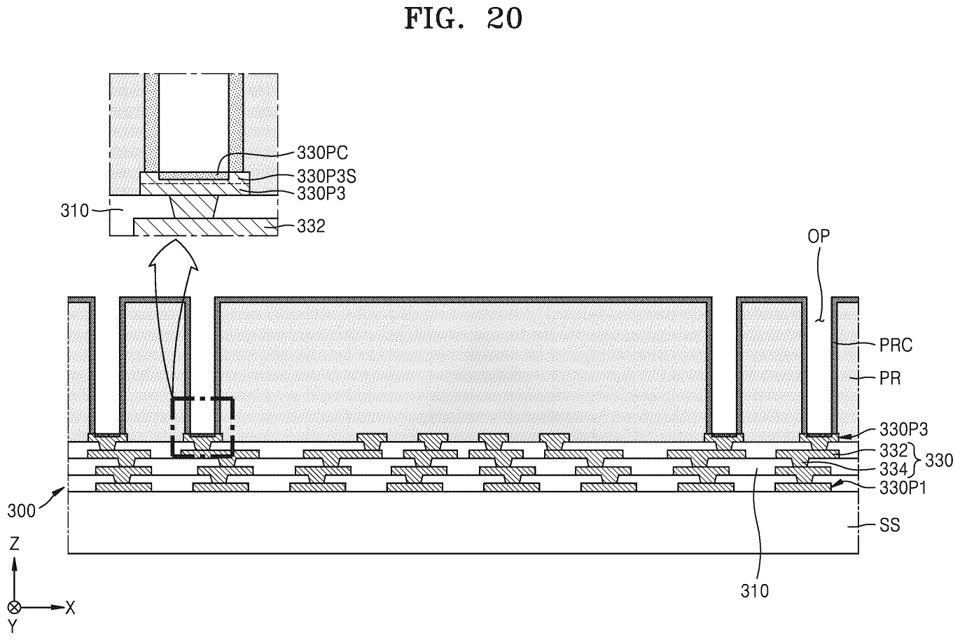

Referring to FIG. 20, based on the ion implantation IIP (see FIG. 19) process, a surface curing layer PRC may be formed on the upper surface and the sidewall of the photoresist PR, and an impurity implantation layer 330PC may be formed on surfaces of the plurality of first upper connection pads 330P3 exposed by the plurality of openings OP.

The upper surface and the sidewall of the photoresist PR may be cured by ion bombardment based on ion implantation IIP (see FIG. 19). In some example embodiments, a total thickness of the photoresist PR may be about 300 μm to about 500 μm, and a thickness of the surface curing layer PRC may be about 0.3 μm to about 1 μm.

Partial portions of the plurality of first upper connection pads 330P3 may be configured with a plurality of metal seed layers 330P3S. Therefore, the impurity implantation layer 330PC may be formed on a surface of the metal seed layer 330P3S in the plurality of first upper connection pads 330P3. Here, in the plurality of first upper connection pads 330P3, the surface roughness of the impurity implantation layer 330PC exposed by the plurality of openings OP may be increased by ion bombardment based on ion implantation IIP (see FIG. 19).

Subsequently, a plating preprocessing process may be performed on a supporting substrate SS where the photoresist PR is formed. The plating preprocessing process may include, for example, rinsing treatment and acid treatment. Here, by adjusting an acid concentration of a solution used in acid treatment, the impurity implantation layer 330PC may remain in the surface of each of the plurality of metal seed layers 330P3S and the surface curing layer PRC of the photoresist PR.

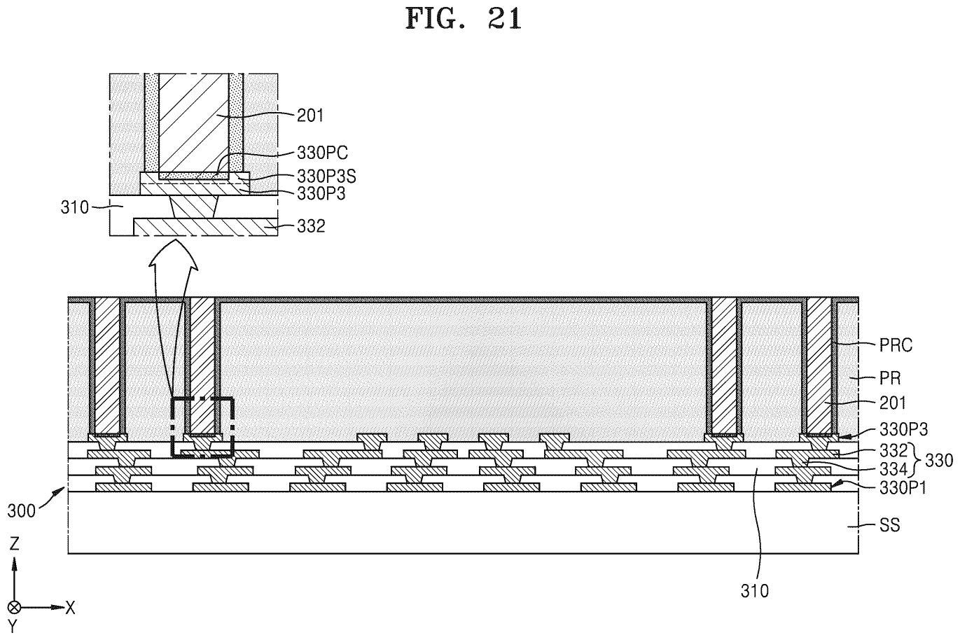

Referring to FIG. 21, a plurality of conductive posts 201 electrically connected to the plurality of first upper connection pads 330P3 disposed in an outer region may be formed by filling a conductive material in the plurality of openings OP (see FIG. 20).

The plurality of conductive posts 201 may be formed by an electro-plating process. In some example embodiments, the plurality of conductive posts 201 satisfying a desired shape may be formed by a single plating process. For example, the conductive material may include Cu or a Cu alloy, but are not limited thereto.

For example, the plurality of metal seed layers 330P3S in the plurality of first upper connection pads 330P3 may function as a seed layer for forming the plurality of conductive posts 201. That is, in a case where the plurality of conductive posts 201 are formed by an electro-plating process, the plurality of metal seed layers 330P3S may provide a path which enables a current to flow, and thus, the plurality of conductive posts 201 may be formed on the impurity implantation layer 330PC of each of the plurality of first upper connection pads 330P3.

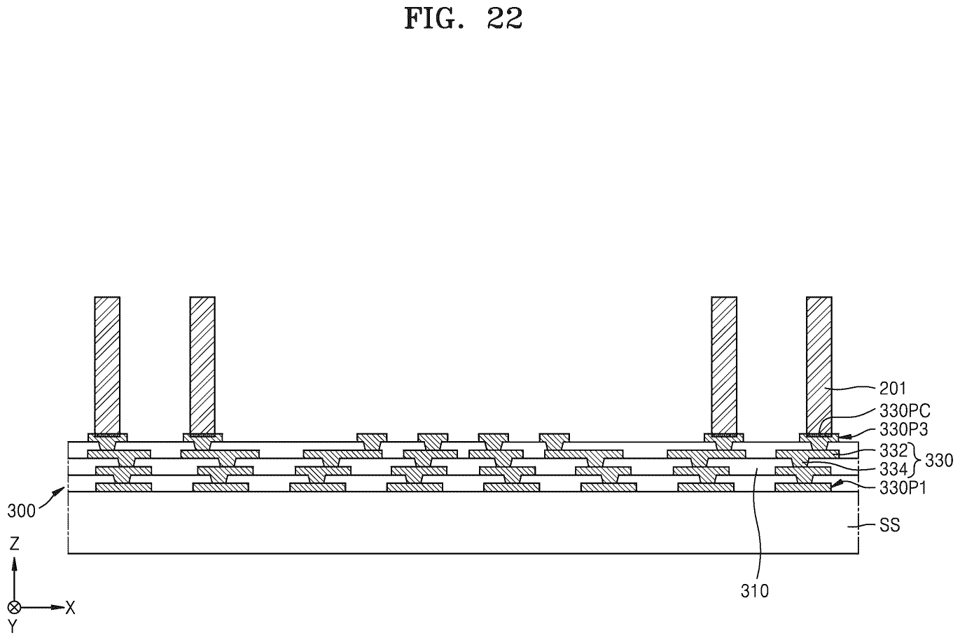

Referring to FIG. 22, after the plurality of conductive posts 201 are formed, the photoresist PR (see FIG. 21) may be removed.

A stripping process and/or an ashing process may be performed for removing the photoresist PR (see FIG. 21). As the photoresist PR (see FIG. 21) is removed, the plurality of conductive posts 201 may be disposed in an outer region of the first wiring structure 300.

Referring again to FIG. 3, as described above, in the method of manufacturing the semiconductor package 20 according to an example embodiment, the degree of curing of a surface of the photoresist PR may increase through the ion implantation IIP, and thus, a phenomenon where compositions of the photoresist PR are eluted to a plating solution in the plating process may decrease, and moreover, a residual material of a cured photoresist PR may be easily removed, thereby enhancing the reliability and productivity of the semiconductor package 20.

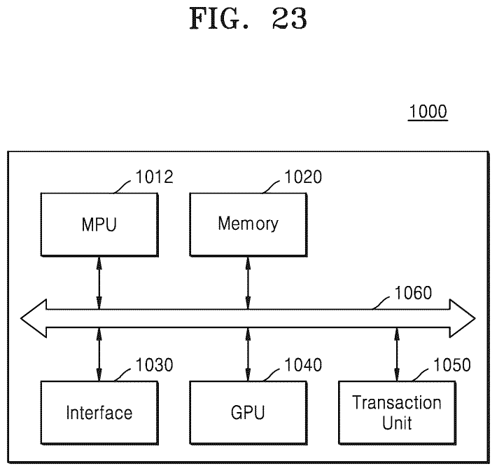

FIG. 23 is a configuration diagram schematically illustrating a configuration of a semiconductor package 1000 according to an example embodiment.

Referring to FIG. 23, the semiconductor package 1000 may include a micro-processing unit 1010, a memory 1020, an interface 1030, a graphics processing unit 1040, transaction unit 1050, and a bus 1060 connecting the elements with each other.

The semiconductor package 1000 may include all of the micro-processing unit 1010 and the graphics processing unit 1040, or may include only one of the micro-processing unit 1010 and the graphics processing unit 1040.

The micro-processing unit 1010 may include a core and a cache. For example, the micro-processing unit 1010 may include a multi-core. Cores of the multi-core may have the same performance or different performances. Also, the cores of the multi-core may be simultaneously activated, or may be activated at different times.

The memory 1020 may store results obtained through processing by the transaction unit 1050, based on control by the micro-processing unit 1010. The interface 1030 may transmit or receive information or a signal to or from external devices. The graphics processing unit 1040 may perform graphics functions. For example, the graphics processing unit 1040 may perform video codec, or may perform three-dimensional (3D) graphics processing. The transaction unit 1050 may perform various functions. For example, when the semiconductor package 1000 is an application processor used in mobile devices, some of the transaction unit 1050 may perform a communication function.

The semiconductor package 1000 may include the semiconductor package 10 described above with reference to FIG. 1 and/or the semiconductor package 20 described above with reference to FIG. 3.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Hereinabove, some example embodiments have been described in the drawings and the specification. While some example embodiments have been described by using the terms described herein, it will be understood by those of ordinary skill in the art that but such terms have been used merely for describing the inventive concepts and have not been used for limiting a meaning or limiting the scope of the inventive concepts defined in the following claims. Therefore, it may be understood by those of ordinary skill in the art that various modifications and other equivalent example embodiments may be implemented from the inventive concepts. Accordingly, the spirit and scope of the inventive concepts may be defined based on the spirit and scope of the following claims.

While the inventive concepts have been particularly shown and described with reference to some example embodiments thereof, it will be understood that various changes in form and details may be made therein without departing from the spirit and scope of the following claims.

What is claimed is:

1. A method of manufacturing a semiconductor package, the method comprising:
forming a first wiring structure including a plurality of first wiring patterns and a first insulation layer surrounding the plurality of first wiring patterns, the first wiring structure including a chip mount region and an outer region surrounding the chip mount region, the plurality of first wiring patterns including a plurality of first connection pads;
coating a photoresist on the first wiring structure and exposing and developing the photoresist to form a plurality of openings on the outer region of the first wiring structure;
performing ion implantation into a surface of the photoresist and surfaces of the plurality of first connection pads exposed by the plurality of openings;
filling the plurality of openings with a conductive material to form a plurality of conductive posts connected to the plurality of first connection pads;
removing the photoresist;
placing a semiconductor chip on the chip mount region of the first wiring structure;
forming an encapsulant surrounding the semiconductor chip and the plurality of conductive posts; and
forming a second wiring structure on the encapsulant, the second wiring structure including a plurality of second wiring patterns, a plurality of second connection pads electrically connected to the plurality of conductive posts, and a second insulation layer surrounding the plurality of second wiring patterns.

2. The method of claim 1, wherein the performing the ion implantation comprises forming a carbon-rich layer on the surface of the photoresist.

3. The method of claim 2, wherein the carbon-rich layer is a cured surface layer, which includes an upper surface and a sidewall of the photoresist cured by the ion implantation.

4. The method of claim 3, wherein
a thickness of the photoresist is 300 μm to 500 μm, and
a thickness of the carbon-rich layer is 0.3 μm to 1 μm.

5. The method of claim 1, wherein the performing the ion implantation comprises forming an impurity implantation layer, into which impurities are implanted by the ion implantation, on each of surfaces of the plurality of first connection pads exposed by the plurality of openings.

6. The method of claim 5, further comprising,
after the ion implantation is performed, removing the impurity implantation layer to form a recess region in each of the surfaces of the plurality of first connection pads.

7. The method of claim 6, wherein
the plurality of conductive posts are formed to fill the recess region of each of the plurality of first connection pads,
a level of an uppermost surface of each of the plurality of first connection pads is higher than a level of a lowermost surface of each of the plurality of conductive posts, and
a level of a lowermost surface of each of the plurality of first connection pads is lower than a level of the lowermost surface of each of the plurality of conductive posts.

8. The method of claim 5, wherein, after the ion implantation is performed, the impurity implantation layer remains in each of the surfaces of the plurality of first connection pads.

9. The method of claim 8, wherein
the plurality of conductive posts are formed to contact the impurity implantation layer of each of the plurality of first connection pads, and
a level of an uppermost surface of each of the plurality of first connection pads is equal to a level of a lowermost surface of each of the plurality of conductive posts.

10. The method of claim 1, wherein
impurities used in the ion implantation are trivalent ions or pentavalent ions, and
a process of forming the plurality of conductive posts is a plating process which uses a surface of each of the plurality of first connection pads, into which the impurities have been implanted, as a seed layer.

11. A method of manufacturing a semiconductor package, the method comprising:
forming a metal seed layer on a metal pad;
coating a photoresist on the metal seed layer and exposing and developing the photoresist to form an opening;
performing ion implantation into a surface of the photoresist and a surface of the metal seed layer exposed by the opening;
filling the opening with a metal material to form a metal post electrically connected to the metal pad; and
removing the photoresist.

12. The method of claim 11, wherein
the opening exposes only a portion of the metal seed layer, and
during the ion implantation, impurities are implanted into the portion of the metal seed layer and both sidewalls of the photoresist defining the opening.

13. The method of claim 12, wherein the performing the ion implantation comprises:
forming a surface curing layer on a surface of the photoresist; and
forming an impurity implantation layer at the portion of the metal seed layer exposed by the opening.

14. The method of claim 13, further comprising,
after the performing of the ion implantation, removing the impurity implantation layer of the metal seed layer to form a recess region in the metal seed layer.

15. The method of claim 14, wherein the metal post is formed by a plating process to fill the recess region of the metal seed layer.

16. The method of claim 13, wherein, after the ion implantation is performed,
the impurity implantation layer of the metal seed layer remains, and
surface roughness of the impurity implantation layer and surface roughness of a peripheral seed layer surrounding the impurity implantation layer in the metal seed layer are different from each other.

17. The method of claim 16, wherein the metal post is formed by a plating process such that the metal post contact the impurity implantation layer of the metal seed layer and does not contact the peripheral seed layer.

18. The method of claim 11, wherein
the metal pad has a stack structure in which a nickel layer and a gold layer are sequentially stacked on a copper layer, and
the metal seed layer has a stack structure in which a copper layer is formed on a titanium layer.

19. A method of manufacturing a semiconductor package, the method comprising:
preparing a supporting substrate;
forming a first wiring structure on the supporting substrate, the first wiring structure including a first chip mount region and a first outer region surrounding the first chip mount region;
coating a photoresist on the first wiring structure and exposing and developing the photoresist to form a plurality of openings on the first outer region of the first wiring structure;
performing ion implantation into an upper surface and a sidewall of the photoresist and an upper surface of the first wiring structure exposed by the plurality of openings;
performing rinsing treatment and acid treatment on the supporting substrate;
filling the plurality of openings with a conductive material to form a plurality of conductive posts;
removing the photoresist;
placing a first semiconductor chip on the first chip mount region of the first wiring structure;
forming an encapsulant surrounding the first semiconductor chip and the plurality of conductive posts;
forming a second wiring structure on the encapsulant, the second wiring structure including a second chip mount region and a second outer region surrounding the second chip mount region; and
placing a second semiconductor chip on the second chip mount region of the second wiring structure.

20. The method of claim 19, wherein
the performing the ion implantation comprises forming a surface curing layer on a surface of the photoresist and forming an impurity implantation layer on an upper surface of the first wiring structure exposed by each of the openings, and
in the performing the rinsing treatment and acid treatment on the supporting substrate, the surface curing layer remains and the impurity implantation layer is removed.
